(19) United States
(12) Patent Application Publication
(10) Pub. No.: US 2015/0294970 A1
(43) Pub. Date: Oct. 15, 2015

(54) CAPACITOR, RESISTOR AND RESISTOR-CAPACITOR COMPONENTS

(71) Applicant: QUALCOMM Incorporated, San Diego, CA (US)

(72) Inventors: Renatas Jakushokas, San Diego, CA (US); Robert Won Chol Kim, San Marcos, CA (US); Vaishnav Srinivas, San Diego, CA (US)

(73) Assignee: QUALCOMM INCORPORATED, San Diego, CA (US)

(21) Appl. No.: 14/252,588

(22) Filed: Apr. 14, 2014

(51) Int. Cl. H01L 27/10; H01L 23/64; H01L 49/02

(52) U.S. Cl. CPC H01L 27/101; H01L 28/40; H01L 28/20; H01L 23/64

(57) ABSTRACT

Capacitor, resistor and resistor-capacitor components are described herein. In one embodiment, a die comprises first and second metal interconnect layers in a back end of line (BEOL) of the die, and an insulator between the first and second metal interconnect layers. The die also comprises a metal-insulator-metal (MIM) capacitor embedded in the insulator, the MIM capacitor comprising a first metal plate, a second metal plate, and a dielectric layer between the first and second metal plates. The die further comprises a metal resistor embedded in the insulator, wherein the metal resistor and the first metal plate of the MIM capacitor are formed from a same metal layer. In one example, the dielectric layer may have a higher dielectric constant than the insulator. In another example, the second metal plate of the MIM capacitor may overlap the metal resistor.

### BACKGROUND

1. Field

Aspects of the present disclosure relate generally to capacitor, resistor and resistor-capacitor (RC) components.

2. Background

Resistors and capacitors may be integrated in a chip and used for a wide range of applications. For example, resistors and capacitors may be used separately or in combination in amplifiers, filters, input/output (I/O) circuits, bias circuits, phase locked loops (PLLs), digital-to-analog converters (DACS), analog-to-digital converters (ADCs), just to name a few. In one example, a capacitor may be used as a decoupling capacitor (decamp) to filter out noise on a power rail. A resistor may be used in combination with the decoupling capacitor to dampen ringing on the power rail (e.g., due to resonance of an inductor-capacitor (LC) circuit coupled to or incorporating the power rail).

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to an aspect, a die is provided. The die comprises first and second metal interconnect layers in a back end of line (BEOL) of the die, and an insulator between the first and second metal interconnect layers. The die also comprises a metal-insulator-metal (MIM) capacitor embedded in the insulator, the MIM capacitor comprising a first metal plate, a second metal plate, and a dielectric layer between the first and second metal plates. The die further comprises a metal resistor embedded in the insulator, wherein the metal resistor and the first metal plate of the MIM capacitor are formed from a same metal layer, and the dielectric layer has a higher dielectric constant than the insulator.

A second aspect relates to a die. The die comprises first and second metal interconnect layers in a back end of line (BEOL) of the die, and an insulator between the first and second metal interconnect layers. The die also comprises a metal-insulator-metal (MIM) capacitor embedded in the insulator, the MIM capacitor comprising a first metal plate, a second metal plate, and a dielectric layer between the first and second metal plates. The die further comprises a metal resistor embedded in the insulator, wherein the metal resistor and the first metal plate of the MIM capacitor are formed from a same metal layer, and the second metal plate of the MIM capacitor overlaps the metal resistor.

A third aspect relates to a die. The die comprises first and second metal interconnect layers in a back end of line (BEOL) of the die, and an insulator between the first and second metal interconnect layers. The die also comprises means for decoupling noise from a power rail, and means for damping ringing on the power rail, wherein the means for decoupling and the means for damping are embedded in the insulator.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 is a top view of an exemplary capacitor-resistor (RC) structure according to an embodiment of the present disclosure.

FIG. 2A is a perspective view of the RC structure of FIG. 1.

FIG. 2B is an unobstructed perspective view of the resistor and the top metal plate of the capacitor of FIG. 1

FIG. 3 is a cross-sectional view of the RC structure of FIG. 1 taken along line 3-3 of FIG. 1.

FIG. 4 is a top view of an exemplary capacitor-resistor (RC) structure in which the resistor is located within an opening in the top metal plate of the capacitor according to an embodiment of the present disclosure.

FIG. 5 is a perspective view of the RC structure of FIG. 4.

FIG. 6 is a cross-sectional view of the RC structure of FIG. 4 taken along line 6-6 of FIG. 4.

FIG. 7 is a top view of a structure comprising a capacitor and a resistor according to an embodiment of the present disclosure.

FIG. 8A is a perspective view of the structure of FIG. 7.

FIG. 8B is an unobstructed perspective view of the resistor and the top metal plate of the capacitor of FIG. 7.

FIG. 9 is a cross-sectional view of the structure of FIG. 7 taken along line 9-9 of FIG. 7.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

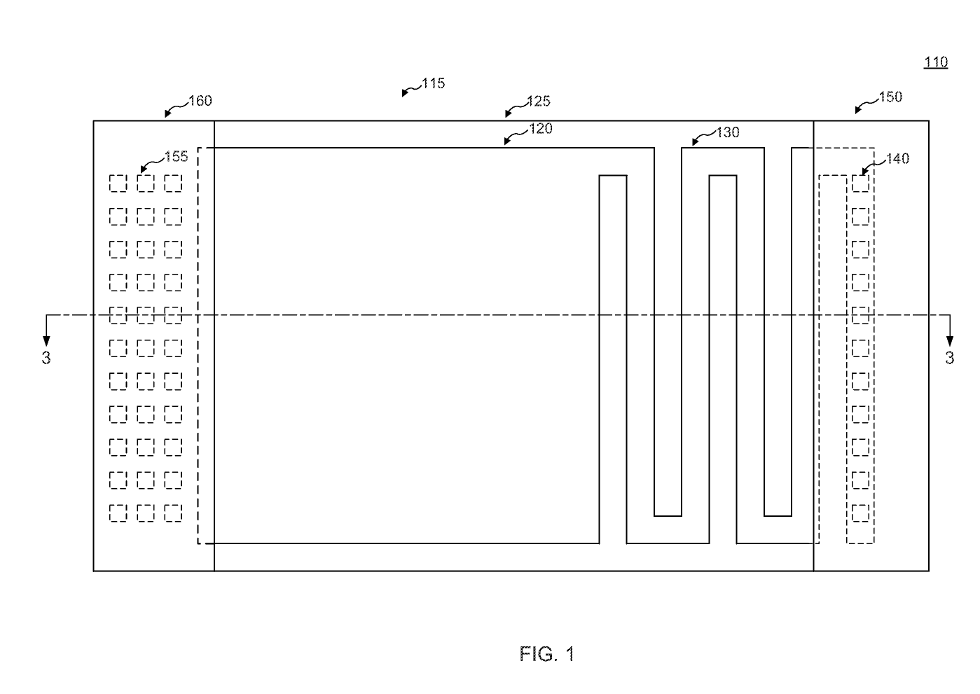

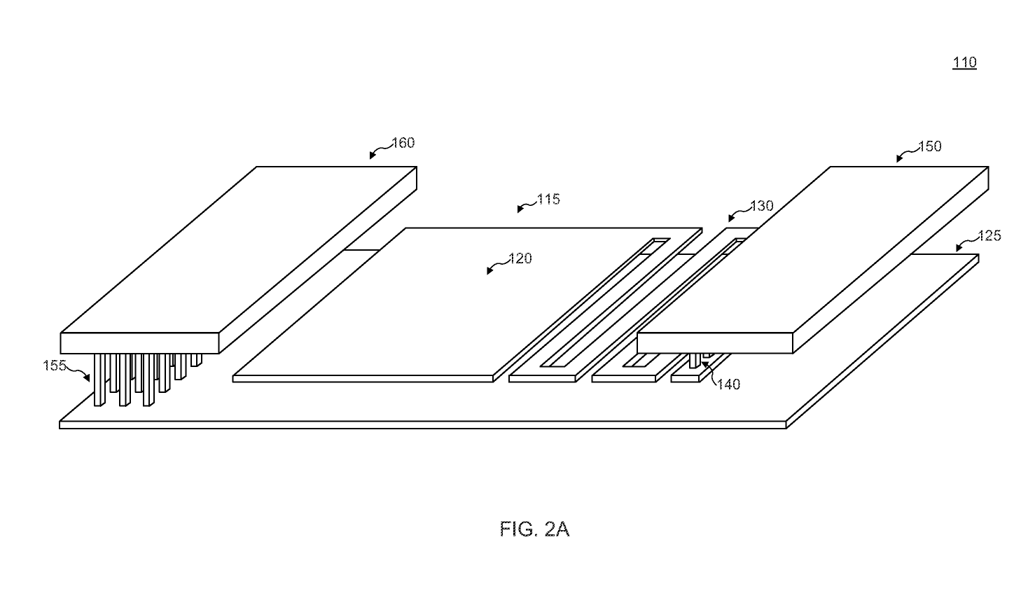

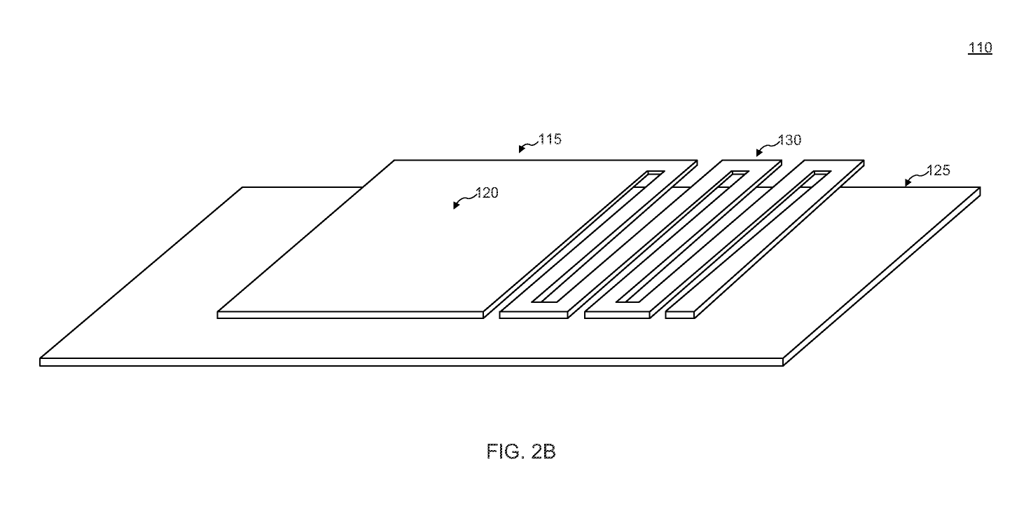

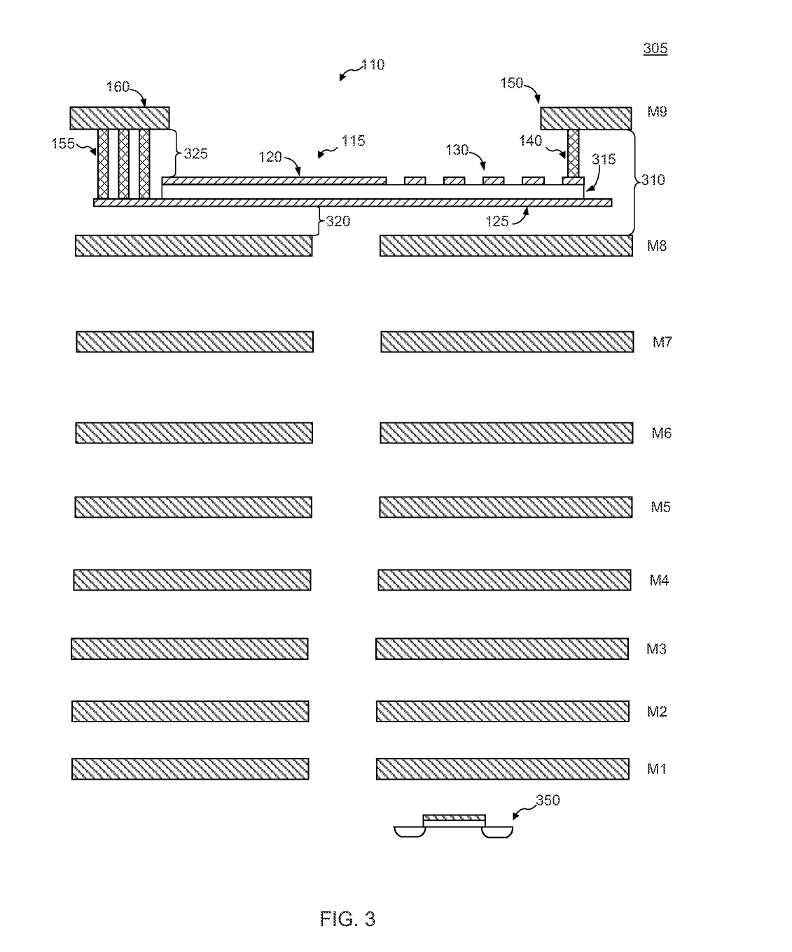

FIGS. 1 and 2A show a resistor-capacitor (RC) structure 110 according to an embodiment of the present disclosure. The RC structure 110 may be integrated in a chip in the back end of line (BEOL) of the chip, as discussed further below. The RC structure 110 comprises a metal-insulator-metal (MIM) capacitor 115 and a metal resistor 130. The MIM capacitor 115 comprises a top metal plate 120, a bottom metal plate 125, and a dielectric layer (shown in FIG. 3) between the top and bottom metal plates 120 and 125.

The top metal plate 120 of the MIM capacitor 115 and the metal resistor 130 are formed from the same metal layer during fabrication. For example, the top metal plate 120 and the metal resistor 130 may be formed from the same metal layer using a lithography, etching process or a damascene process. In the example in FIGS. 1 and 2A, the top metal plate 120 and the metal resistor 130 are contiguous. The bottom metal plate 125 may extend underneath the metal resistor 130, as shown in FIGS. 1 and 2A.

The metal resistor 130 may be long and narrow with a resistance approximately given by:

$$R = \frac{ρ \cdot L}{t \cdot W} \qquad ( 1 )$$

Where R is the resistance of the resistor 130, p is the resistivity of the resistor 130, L is the length of the resistor 130, t is the thickness of the resistor 130, and W is the width of the resistor 130. In the example in FIGS. 1 and 2A, the metal resistor 130 has a serpentine layout with a resistive path that snakes back and forth. This allows the metal resistor 130 to be long to achieve a desired resistance while fitting within a compact space. It is to be appreciated that the metal resistor 130 is not limited to the exemplary shape shown in FIGS. 1 and 2A, and may have any planar shape that achieves a desired resistance.

The metal resistor 130 has a first end coupled to metal interconnect 150 by one or more vias 140, and a second end coupled to the top metal plate 120 of the MIM capacitor 115. In the example in FIGS. 1 and 2A, the second end of the metal resistor 130 directly contacts the top metal plate 120 since the resistor 130 is contiguous with the top metal plate 120. The bottom metal plate 125 of the MIM capacitor 115 is coupled to metal interconnect 160 by one or more vias 155. Metal interconnects 150 and 160 may be formed from the same metal interconnect layer during fabrication, as discussed further below. Thus, in this example, the resistor 130 and the MIM capacitor 115 are coupled between metal interconnects 150 and 160.

FIG. 2B shows the RC structure 110 without the metal interconnects 150 and 160 and vias 140 and 155 to provide an unobstructed view of the resistor 130 and the top metal plate 120 of the MIM capacitor 115.

FIG. 3 is a cross-sectional view of the RC structure 110 in a chip (die) 305 according to an embodiment of the present disclosure. The chip 305 comprises a plurality of metal interconnect layers with insulators between the metal interconnect layers. In the example in FIG. 3, the chip 305 comprises at least nine metal interconnect layers (labeled M1 to M9). M1 is the bottom-most metal interconnect layer and M9 is the top-most metal interconnect layer shown in FIG. 3. The metal interconnect layers M1 to M9 may be used to interconnect various components of the chip 305. For ease of illustration, the structures (e.g., vias) interconnecting the metal interconnect layers M1 to M9 are not shown in FIG. 3. The metal interconnect layers M1 to M9 may comprise copper, aluminum, tungsten, other type of metal, or any combination thereof

In the example in FIG. 3, metal interconnect layer M1 is located above the front end of line (FEOL) of the chip 305, where active devices (e.g., metal-oxide-semiconductor field-effect transistors MOSFETs) of the chip 305 are formed. FIG. 3 shows an example of a MOSFET 350 located below metal interconnect layer M1 in the FEOL of the chip 305.

In the example in FIG. 3, the MIM capacitor 115 and the metal resistor 130 of the RC structure 110 are located between metal interconnect layers M9 and M8. In this example, metal interconnects 150 and 160 are formed from metal interconnect layer M9. For example, metal interconnects 150 and 160 may be formed from metal interconnect layer M9 using a lithography/etching process or a damascene process. Also, in this example, the MIM capacitor 115 and the metal resistor 130 are embedded in the insulator 310 (e.g., silicon oxide, silicon nitride, etc.) between metal interconnect layers M9 and M8. Metal interconnect layer M9 may have a thickness that is larger than the thickness of each of the top metal plate 120 and the bottom metal plate 125.

FIG. 3 shows the dielectric layer 315 between the top metal plate 120 and the bottom metal plate 125. In the example in FIG. 3, the dielectric layer 315 extends between the resistor 130 and the bottom metal plate 125, although it is to be appreciated that this need not to be the case. The dielectric layer 315 may have a high dielectric k constant to increase the capacitance density of the MIM capacitor 115. In this regard, the dielectric layer 315 may comprise one or more high-k materials such as, for example, hafnium-based high-k materials, tantalum-based high-k materials or any combination thereof. Hafnium-based high-k materials and tantalum-based high-k materials may have a dielectric constant k of 20 or greater. In one aspect, the dielectric layer 315 has a dielectric constant k of 15 or more. In another aspect, the dielectric layer 315 has a dielectric constant k of 20 or more.

In one embodiment, the insulator 310 has a lower dielectric constant k than the dielectric layer 315 of the MIM capacitor 115 to minimize parasitic capacitances. For example, the portion 325 of the insulator 310 between the top metal plate 120 and metal interconnect layer M9 may have a lower dielectric constant k to minimize parasitic capacitance between the top metal plate 120 and metal interconnect layer M9. Similarly, the portion 320 of the insulator 310 between the bottom metal plate 125 and metal interconnect layer M8 may have a lower dielectric constant k to minimize parasitic capacitance between the bottom metal layer 125 and metal interconnect layer M8. For example, the insulator 310 may comprise silicon oxide which has a relatively low dielectric constant k of approximately 3.9. In one aspect, the insulator 310 has a dielectric constant k of 8 or less. In another aspect, the insulator 310 has a dielectric constant k of 5 or less.

It is to be appreciated that embodiments of the present disclosure are not limited to the example shown in FIG. 3. For example, it is to be appreciated that the MIM capacitor 115 and the metal resistor 130 are not limited to being located between interconnect layers M9 and M8, and that, in general, the MIM capacitor 115 and the metal resistor 130 may be located between any two adjacent interconnect layers in the BEOL. It is also to be appreciated that the spacing between adjacent interconnect layers may vary. For example, the spacing between two upper interconnect layers (e.g., interconnect layers M9 and M8) may be larger than the spacing between two lower interconnect layers (e.g., interconnect layers M2 and M1). Further, it is to be appreciated that the thicknesses of the interconnect layers may vary. For example, the thickness of an upper interconnect layer (e.g., interconnect layer M9) may be greater than the thickness of a lower interconnect layer (e.g., interconnect layer M1).

In one embodiment, metal interconnect 150 may be coupled to an upper power rail (e.g., Vdd) and metal interconnect 160 may be coupled to a lower power rail (e.g., Vss) or grounded. In this embodiment, the MIM capacitor 115 may be used as a decoupling capacitor to decouple noise from the upper power rail and the resistor 130 may be used as a damping resistor to dampen ringing on the upper power rail. In another embodiment, metal interconnects 150 and 160 may be coupled to a circuit (not shown) in the chip 305 that uses the MIM capacitor 115 and resistor 130, such as, for example, a filter, an amplifier, an I/O circuit, a biasing circuit, a PLL, a DAC, a ADC, etc. The vias 140 and 155 coupling the MIM capacitor 115 and the resistor 130 to metal interconnects 150 and 160 may be formed, for example, by etching corresponding holes in the insulator 310 and filling the holes with conductive material (e.g., tungsten).

Placing the RC structure 110 between two upper metal interconnect layers (e.g., metal interconnect layers M9 and M9) in the BEOL may provide one or more of the following advantages. First, the spacing between the upper metal interconnects layers may be larger than the spacing between lower metal interconnect layers. As a result, there may be more space between the upper metal interconnect layers to accommodate the RC structure 110, allowing the RC structure to be larger. Also, there may be much fewer vias between the upper metal interconnect layers compared with lower metal interconnect layers. This is because lower metal interconnect layers are typically used to interconnect a large number of devices (e.g., active devices) in the chip 305, which requires a large number of vias. Because there are fewer vias between the upper metal interconnect layers, there is more space between the vias to accommodate the RC structure 110.

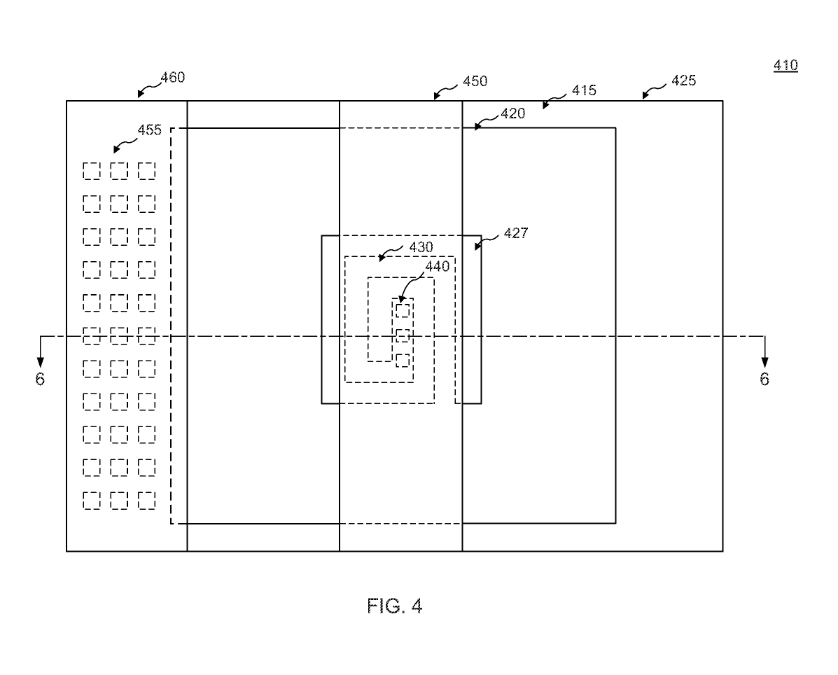

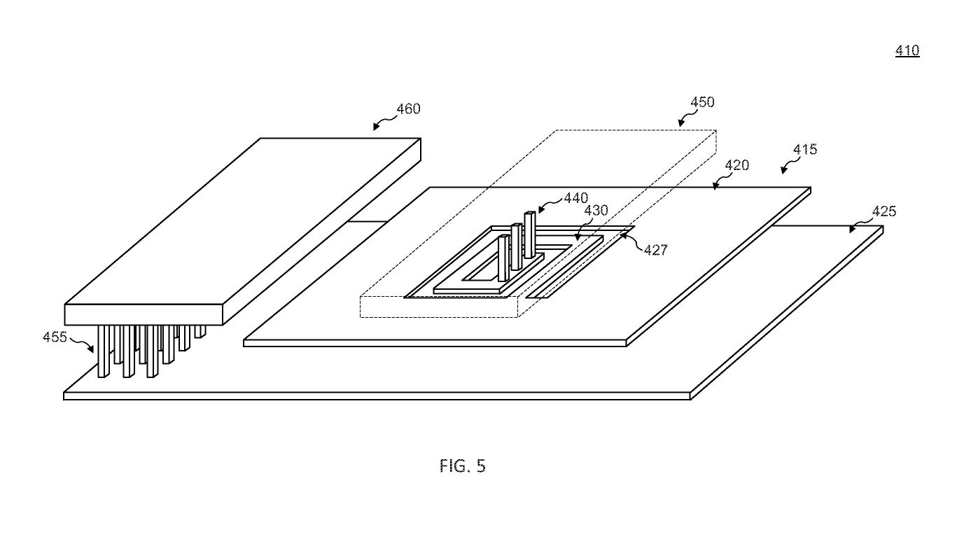

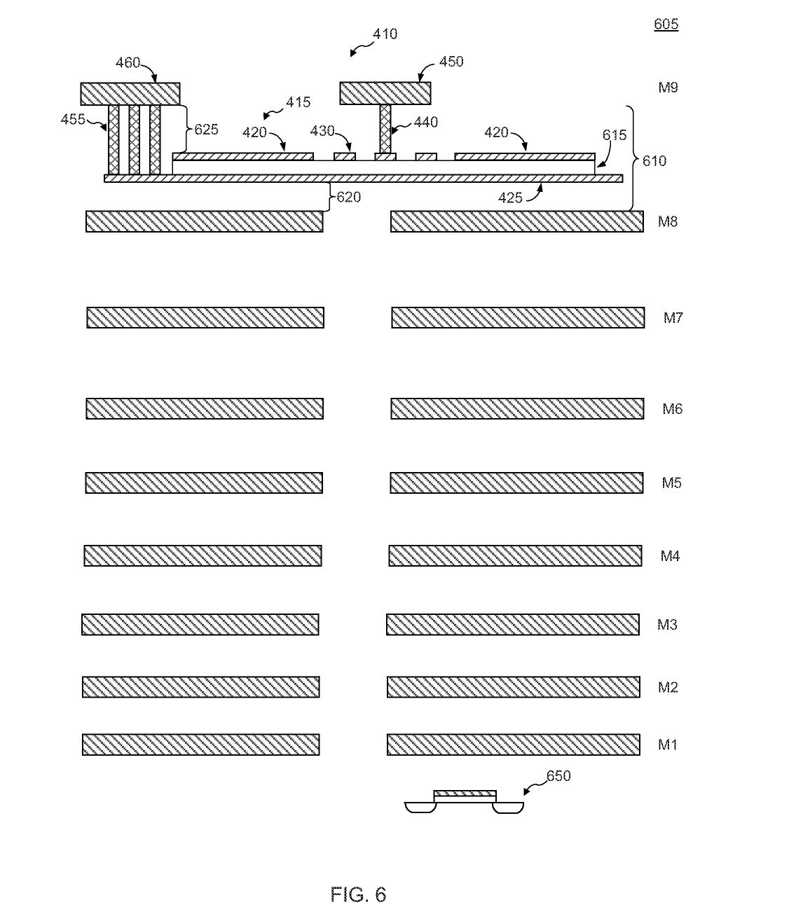

FIGS. 4 and 5 show a resistor-capacitor (RC) structure 410 according to another embodiment of the present disclosure. The RC structure 410 may be integrated in a chip in the back end of line (BEOL) of the chip, as discussed further below. The RC structure 410 comprises a metal-insulator-metal (MIM) capacitor 415 and a metal resistor 430. The MIM capacitor 415 comprises a top metal plate 420, a bottom metal plate 425, and a dielectric layer (shown in FIG. 6) between the top and bottom metal plates 420 and 425. In this embodiment, the resistor 430 is formed within an opening 427 in the top metal plate 420 and overlaps the bottom metal plate 425.

The top metal plate 420 of the MIM capacitor 415 and the metal resistor 430 are formed from the same metal layer during fabrication, and are contiguous. Although the opening 427 is located approximately at the center of the top metal plate 420 in the example in FIGS. 4 and 5, it is to be appreciated that the opening 427 may be located anywhere within the top metal plate 420 (e.g., located off center). Further, although the opening 427 surrounds the metal resistor 430 on four sides in the example in FIGS. 4 and 5, it is to be appreciated that the opening 427 may surround the metal resistor 430 on three sides.

In the example in FIGS. 4 and 5, the metal resistor 430 has a spiral layout within the opening 427 in the top metal plate 420. Alternatively, the metal resistor 420 may have a serpentine layout that snakes back and forth similar to the resistor layout shown in FIGS. 1 and 2A. Both layouts allow the resistor 420 to be long and narrow while fitting within the opening 427 in the top metal plate 420. It is to be appreciated that the resistor 430 may have other planar shapes that can fit within the opening 427 in the top metal plate 420.

The metal resistor 430 has a first end coupled to metal interconnect 450 by one or more vias 440, and a second end coupled to the top metal plate 420 of the MIM capacitor 415. In FIG. 5, metal interconnect 450 is shown in phantom so as not to obstruct the view of the resistor 430. In this example, the second end of the metal resistor 430 directly contacts the top metal plate 420 since the resistor 430 is contiguous with the top metal plate 420. The bottom metal plate 425 is coupled to metal interconnect 460 by one or more vias 455. Metal interconnects 450 and 460 may be formed from the same metal interconnect layer during fabrication, as discussed further below. Thus, in this example, the resistor 430 and the MIM capacitor 415 are coupled between metal interconnects 450 and 460.

FIG. 6 is a cross-sectional view of the RC structure 410 in a chip (die) 605 according to an embodiment of the present disclosure. The chip 605 comprises a plurality of metal interconnect layers with insulators between the metal interconnect layers. In the example in FIG. 6, the chip 605 comprises at least nine metal interconnect layers (labeled M1 to M9). For ease of illustration, the structures (e.g., vias) interconnecting the metal interconnect layers M1 to M9 are not shown in FIG. 6. In the example in FIG. 6, the bottom-most metal interconnect layer M1 is located above the front end of line (FEOL) of the chip 605, where active devices (MOSFETs) of the chip 605 are formed. FIG. 6 shows an example of a MOSFET 650 located below metal interconnect layer M1.

In the example in FIG. 6, the MIM capacitor 415 and the metal resistor 430 of the RC structure 410 are located between metal interconnect layers M9 and M8. Metal interconnects 450 and 460 are formed from metal interconnect layer M9. The MIM capacitor 415 and the metal resistor 430 are embedded in the insulator 610 (e.g., silicon oxide, silicon nitride, etc.) between metal interconnect layers M9 and M8. Metal interconnect layer M9 may have a thickness that is larger than the thickness of each of the top metal plate 420 and the bottom metal plate 425.

In this embodiment, the metal resistor 430 is located within the opening 427 in the top metal plate 420. The opening 427 may be located anywhere within the top metal plate 420, providing great flexibility in the location of the metal resistor 430. This in turn provides great flexibility in the placement of interconnect metal 450, which is coupled to the metal resistor 430. This is advantageous, for example, when placement of interconnect metal 450 is restricted (e.g., due to chip design, design rules, etc.).

In one embodiment, metal interconnect 450 may be coupled to an upper power rail (e.g., Vdd) and metal interconnect 460 may be coupled to a lower power rail (e.g., Vss) or grounded. In this embodiment, the MIM capacitor 415 may be used as a decoupling capacitor to decouple noise from the upper power rail and the resistor 430 may be used as a damping resistor to dampen ringing on the upper power rail. In another embodiment, metal interconnects 450 and 460 may be coupled to a circuit (not shown) in the chip 605 that uses the MIM capacitor 415 and resistor 430, such as, for example, a filter, an amplifier, an I/O circuit, a biasing circuit, a PLL, a DAC, a ADC, etc.

FIG. 6 shows the dielectric layer 615 between the top metal plate 420 and the bottom metal plate 425 of the MIM capacitor 415. The dielectric layer 615 may also be between the resistor 430 and the bottom metal plate 425. The dielectric layer 415 may have a high dielectric k constant to increase the capacitance density of the MIM capacitor 415. In this regard, the dielectric layer 615 may comprise one or more high-k materials such as, for example, hafnium-based high-k materials, tantalum-based high-k materials or any combination thereof. In one aspect, the dielectric layer 615 has a dielectric constant k of 15 or more. In another aspect, the dielectric layer 615 has a dielectric constant k of 20 or more.

In one embodiment, the insulator 610 has a lower dielectric constant k than the dielectric layer 615 of the MIM capacitor 415 to minimize parasitic capacitances. For example, the portion 625 of the insulator 610 between the top metal plate 420 and metal interconnect layer M9 may have a lower dielectric constant k to minimize parasitic capacitance between the top metal plate 420 and metal interconnect layer M8 and the portion 620 of the insulator 610 between the bottom metal plate 425 and metal interconnect layer M8 may have a lower dielectric constant k to minimize parasitic capacitance between the bottom metal layer 425 and metal interconnect layer M8. In one aspect, the insulator 610 has a dielectric constant k of 8 or less. In another aspect, the insulator 610 has a dielectric constant k of 5 or less.

It is to be appreciated that embodiments of the present disclosure are not limited to the example shown in FIG. 6. For example, it is to be appreciated that the MIM capacitor 415 and the resistor 430 are not limited to being located between interconnect layers M9 and M8, and that, in general, the MIM capacitor 415 and the resistor 430 may be located between any two adjacent interconnect layers in the BEOL.

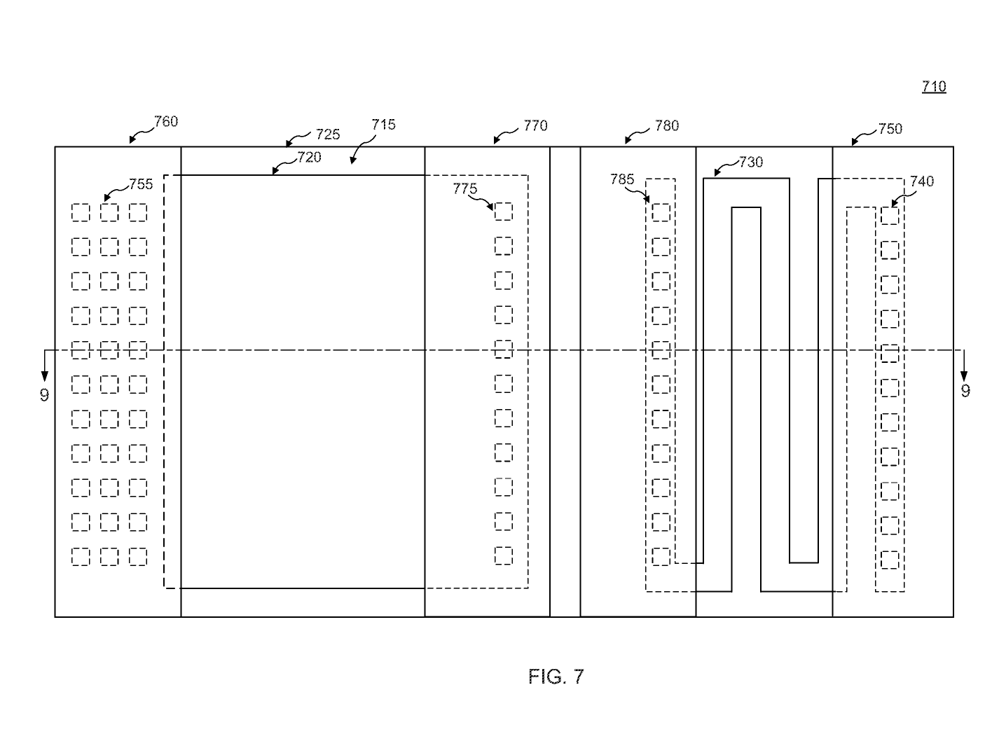

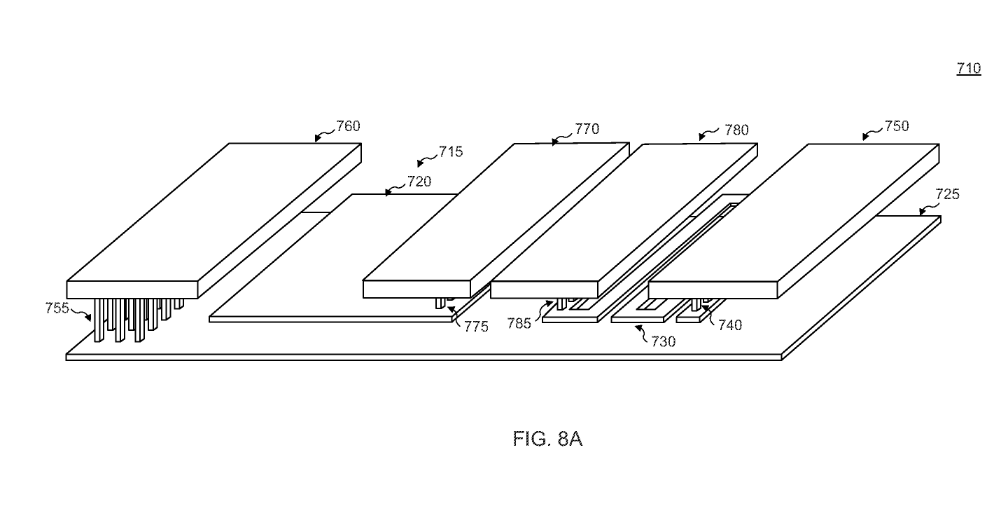

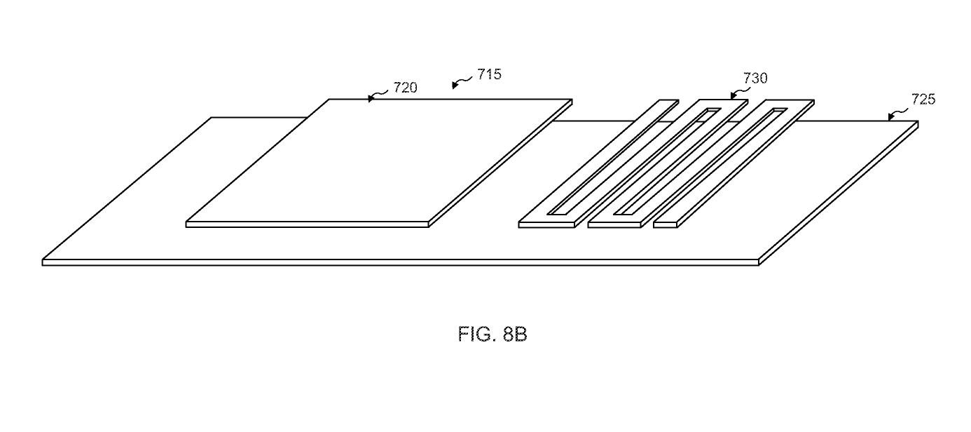

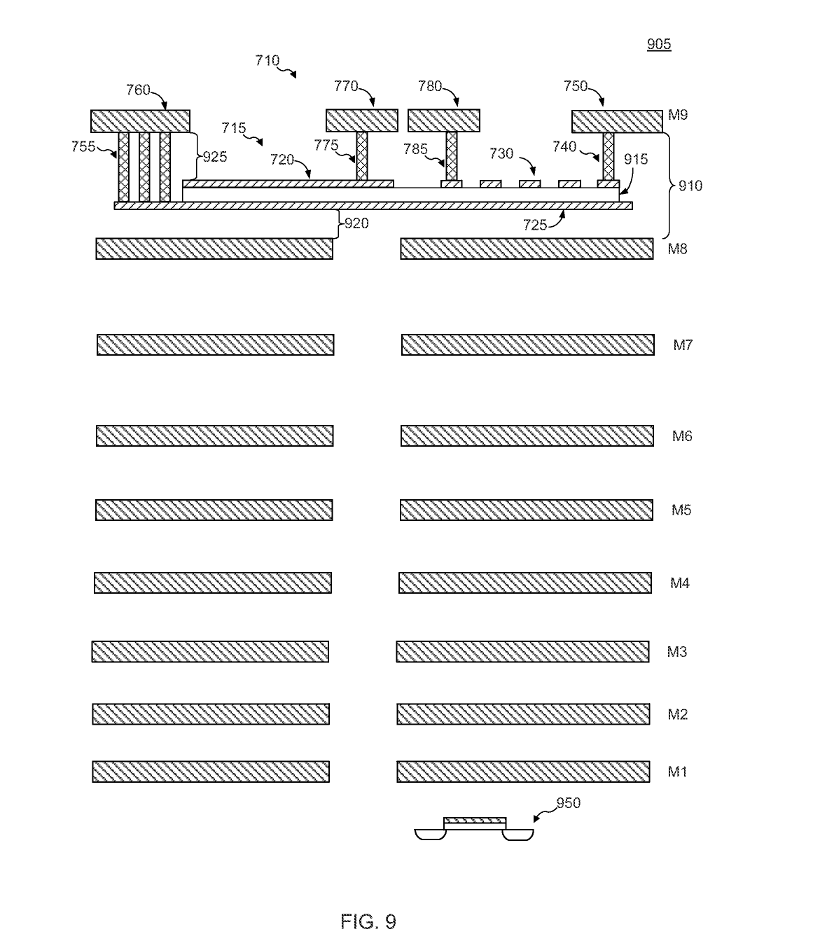

FIGS. 7 and 8A show a structure 710 comprising a MIM capacitor 715 and a metal resistor 730 according to an embodiment of the present disclosure. The MIM capacitor 715 and the metal resistor 730 may be integrated in a chip in the back end of line (BEOL) of the chip, as discussed further below. The MIM capacitor 715 comprises a top metal plate 720, a bottom metal plate 725, and a dielectric layer (shown in FIG. 9) between the top and bottom metal plates 720 and 725. In this embodiment, the resistor 730 and the top metal plate 720 of the MIM capacitor 715 are separated.

The top metal plate 720 of the MIM capacitor 715 and the metal resistor 730 are formed from the same metal layer during fabrication. For example, the top metal plate 720 and the metal resistor 730 may be formed from the same metal layer using a lithography/etching process or a damascene process.

In the example in FIGS. 7 and 8A, the metal resistor 730 has a serpentine layout with a resistive path that snakes back and forth. However, it is to be appreciated that the metal resistor 730 is not limited to the exemplary shape shown in FIGS. 7 and 8A, and may have any planar shape that achieves a desired resistance.

The metal resistor 730 has a first end coupled to metal interconnect 750 by one or more vias 740, and a second end coupled to metal interconnect 780 by one or more vias 785. The top metal plate 720 of the MIM capacitor 715 is coupled to metal interconnect 770 by one or more vias 775, and the bottom metal plate 725 of the MIM capacitor 715 is coupled to metal interconnect 760 by one or more vias 755. Metal interconnects 750, 760, 770 and 780 may be formed from the same metal interconnect layer during fabrication, as discussed further below. The bottom metal plate 725 may extend beneath the resistor 730 as shown in FIGS. 7 and 8A, although it is to be appreciated that this need not be the case.

FIG. 8B shows the structure 710 without the metal interconnects 750, 760, 770 and 780 and vias 740, 755, 775 and 785 to provide an unobstructed view of the resistor 730 and the MIM capacitor 715.

FIG. 9 shows a cross-sectional view of the MIM capacitor 715 and the metal resistor 730 in a chip (die) 905 according to an embodiment of the present disclosure. The chip 905 comprises a plurality of metal interconnect layers with insulators between the metal interconnect layers. In the example in FIG. 9, the chip 905 comprises at least nine metal interconnect layers (labeled M1 to M9). For ease of illustration, the structures (e.g., vias) interconnecting the metal interconnect layers M1 to M9 are not shown in FIG. 9. In the example in FIG. 9, the bottom-most metal interconnect layer M1 is located above the front end of line (FEOL) of the chip 905, where active devices (MOSFETs) of the chip 905 are formed. FIG. 9 shows an example of a MOSFET 950 located below metal interconnect layer M1.

In the example in FIG. 9, the MIM capacitor 715 and the metal resistor 730 are located between metal interconnect layers M9 and M8. Metal interconnects 750, 760, 770 and 780 are formed from metal interconnect layer M9. The MIM capacitor 715 and the metal resistor 730 are embedded in the insulator 910 (e.g., silicon oxide, silicon nitride, etc.) between metal interconnect layers M9 and M8. Metal interconnect layer M9 may have a thickness that is larger than the thickness of each of the top metal plate 720 and the bottom metal plate 725.

FIG. 9 shows the dielectric layer 915 between the top metal plate 720 and the bottom metal plate 725 of the MIM capacitor 415. The dielectric layer 915 may also extend underneath the resistor 730. The dielectric layer 915 may have a high dielectric k constant to increase the capacitance density of the MIM capacitor 715. In this regard, the dielectric layer 715 may comprise one or more high-k materials such as, for example, hafnium-based high-k materials, tantalum-based high-k materials or any combination thereof. In one aspect, the dielectric layer 915 has a dielectric constant k of 15 or more. In another aspect, the dielectric layer 915 has a dielectric constant k of 20 or more.

In one embodiment, the insulator 910 has a lower dielectric constant k than the dielectric layer 915 of the MIM capacitor 715 to minimize parasitic capacitances. For example, the portion 925 of the insulator 910 between the top metal plate 720 and metal interconnect layer M9 may have a lower dielectric constant k to minimize parasitic capacitance between the top metal plate 720 and metal interconnect layer M9 and the portion 920 of the insulator 910 between the bottom metal plate 725 and metal interconnect layer M8 may have a lower dielectric constant k to minimize parasitic capacitance between the bottom metal layer 725 and metal interconnect layer M8. In one aspect, the insulator 910 has a dielectric constant k of 8 or less. In another aspect, the insulator 910 has a dielectric constant k of 5 or less.

In this embodiment, the metal resistor 730 and the MIM capacitor 715 may be separately used. For example, the metal resistor 730 and the MIM capacitor 715 may be coupled to different circuits in the chip 905. More particularly, the MIM capacitor 715 may be coupled to one of the circuits through metal interconnects 760 and 770, and the metal resistor 730 may be coupled to a different one of the circuits through metal interconnects 750 and 780. Alternatively, the MIM capacitor 715 and the metal resistor 130 may be coupled to the same circuit for use by the same circuit (e.g., amplifier, I/O circuit, etc.).

Although the MIM capacitor 715 and the metal resistor 730 are shown in close proximity to one another in FIG. 9 for ease of illustration, it is to be appreciated that the MIM capacitor 715 and the metal resistor 730 may be spaced farther apart in the chip 905. In general, it is to be appreciated that the figures are not drawn to scale.

Further, it is to be appreciated that the chip 905 may comprise any number of metal resistors. For example, the metal resistor 730 shown in FIG. 9 may be replicated in the chip 905 to provide a plurality of metal resistors. The metal resistors may have the same length or different lengths to provide different resistances. Each of the metal resistors may be coupled to a pair of metal interconnects by vias to enable a circuit that uses the resistor to be coupled to the resistor. The metal resistors may be formed from the same metal layer during fabrication (e.g., using a lithography/etching process or a damascene process).

Further, it is to be appreciated that the chip 905 may comprise any number of MIM capacitors. For example, the MIM capacitor 715 shown in FIG. 9 may be replicated in the chip 905 to provide a plurality of MIM capacitors. The MIM capacitors may have the same area or different areas to provide different capacitances. Each of the MIM capacitors may be coupled to a pair of metal interconnects by vias to enable a circuit that uses the MIM capacitor to be coupled to the MIM capacitor. The top metal plates of the MIM capacitors may be formed from the same metal layer during fabrication (e.g., using a lithography/etching process or a damascene process). Further, the top metal plates of the MIM capacitors may be formed from the same metal layer as metal resistors in the chip 905.

In one example, a plurality of the MIM capacitors may be used as decoupling capacitors. In this example, each of the plurality of MIM capacitors may be coupled between power rails. Also, the plurality of MIM capacitors may be distributed throughout the chip 905.

It is also to be appreciated that a chip may comprise a combination of structures according to various embodiments of the present disclosure. For example, a chip may comprise both an RC structure (e.g., RC structure 110 and/or RC structure 410) and the MIM capacitor 715 and resistor 730 shown in FIG. 9. In this example, the RC structure, the MIM capacitor 715 and the resistor 730 may be located between two upper metal interconnect layers of the chip (e.g., metal interconnect layers M9 and M8). The metal resistor 730 and the resistor in the RC structure may be formed from the same metal layer. The top metal plate 720 of the MIM capacitor 715 and the top metal plate of the MIM capacitor in the RC structure may be formed from the same metal layer. Further, the top metal plate 720 of the MIM capacitor 715, the top metal plate of the MIM capacitor in the RC structure, the metal resistor 730, and the metal resistor in the RC structure may all be formed from the same metal layer (e.g., using a lithography/etching process or a damascene process).

It is also to be appreciated that metal interconnects 770 and 780 may be coupled together (e.g., may be contiguous). This may be done, for example, when the top plate 720 of the MIM capacitor 715 and one end of the resistor 730 are coupled to a common circuit node or power rail (e.g., Vdd). In this example, the top plate 120 of the MIM capacitor 715 and the one end of the resistor 730 may be contiguous. It is also to be appreciated that metal interconnects 760 and 750 may be coupled together (e.g., may be contiguous). This may be done, for example, when the bottom plate 725 of the MIM capacitor 715 and the other end of the resistor 730 are coupled to a common circuit node or power rail (e.g., Vss).

It is to be appreciated that directional terms used herein (e.g., top, bottom, upper, lower, etc.) may refer to the relative positions of elements when the respective chip is face up. The directional terms are relative and no particular absolute orientation should be inferred.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A die, comprising:
first and second metal interconnect layers in a back end of line (BEOL) of the die;
an insulator between the first and second metal interconnect layers;
a metal-insulator-metal (MIM) capacitor embedded in the insulator, the MIM capacitor comprising:
a first metal plate;
a second metal plate; and
a dielectric layer between the first and second metal plates; and
a metal resistor embedded in the insulator, wherein the metal resistor and the first metal plate of the MIM capacitor are formed from a same metal layer, and the dielectric layer has a higher dielectric constant than the insulator.

2. The die of claim 1, wherein the first metal plate of the MIM capacitor and the metal resistor are contiguous.

3. The die of claim 2, wherein the metal resistor has one of a serpentine shape and a spiral shape.

4. The die of claim 2, further comprising:
a first metal interconnect;
a first via coupling one end of the metal resistor to the first metal interconnect, wherein another end of the metal resistor contacts the first metal plate of the MIM capacitor;
a second metal interconnect; and
a second via coupling the second metal plate of the MIM capacitor to the second metal interconnect, wherein the first and second metal interconnects are formed from the first metal interconnect layer.

5. The die of claim 2, wherein the first metal plate of the MIM capacitor has an opening, and the metal resistor is located within the opening.

6. The die of claim 5, wherein the metal resistor has one of a serpentine shape and a spiral shape.

7. The die of claim 5, further comprising:
a first metal interconnect;
a first via coupling one end of the metal resistor to the first metal interconnect, wherein another end of the metal resistor contacts the first metal plate of the MIM capacitor;
a second metal interconnect; and
a second via coupling the second metal plate of the MIM capacitor to the second metal interconnect, wherein the first and second metal interconnects are formed from the first metal interconnect layer.

8. The die of claim 5, wherein the opening surrounds the metal resistor on at least three sides.

9. The die of claim 1, wherein the second metal plate of the MIM capacitor overlaps the metal resistor.

10. The die of claim 1, further comprising:
a plurality of metal interconnect layers beneath the first and second metal interconnect layers; and
a plurality of active devices beneath the plurality of metal interconnect layers.

11. The die of claim 1, wherein the dielectric layer has a dielectric constant of 15 or higher.

12. The die of claim 11, wherein the insulator has a dielectric constant of eight or less.

13. A die, comprising:
first and second metal interconnect layers in a back end of line (BEOL) of the die;
an insulator between the first and second metal interconnect layers;
a metal-insulator-metal (MIM) capacitor embedded in the insulator, the MIM capacitor comprising:
a first metal plate;
a second metal plate; and
a dielectric layer between the first and second metal plates; and
a metal resistor embedded in the insulator, wherein the metal resistor and the first metal plate of the MIM capacitor are formed from a same metal layer, and the second metal plate of the MIM capacitor overlaps the metal resistor.

15. The die of claim 13, wherein the first metal plate of the MIM capacitor and the metal resistor are contiguous.

16. The die of claim 15, wherein the metal resistor has one of a serpentine shape and a spiral shape.

17. The die of claim 15, wherein the first metal plate of the MIM capacitor has an opening, and the metal resistor is located within the opening.

18. The die of claim 17, wherein the metal resistor has one of a serpentine shape and a spiral shape.

19. The die of claim 17, wherein the opening surrounds the metal resistor on at least three sides.

20. A die, comprising:
first and second metal interconnect layers in a back end of line (BEOL) of the die;
an insulator between the first and second metal interconnect layers;
means for decoupling noise from a power rail; and
means for damping ringing on the power rail, wherein the means for decoupling and the means for damping are embedded in the insulator.
